(19) United States
(12) Patent Application Publication
(10) Pub. No.: US 2005/0000424 A1
(43) Pub. Date: Jan. 6, 2005

(54) Method and system for thermal spraying

(76) Inventors: Tsuyoshi Itsukaichi, Iwakura-shi (JP); Satoru Osawa, Ichinomiya-shi (JP)

Correspondence Address: Vidas Arrett & Steinkraus, Suite 2000, 6109 Blue Circle Drive, Minnetonka, MN, 55343, US

(21) Appl. No.: 10/492,824

(22) PCT Filed: Oct. 15, 2002
(86) PCT No.: PCT/JP02/10685

(30) Foreign Application Priority Data
Oct. 15, 2001 (JP) 2001-317497

(51) Int. Cl. H05H 1/26; C23C 16/00

(52) U.S. Cl. 118/715; 427/446

(57) ABSTRACT

A thermal spraying method and thermal spraying system of the present invention jets thermal spraying powder supplied from a feeder through a connecting conduit by softening or melting the thermal spraying powder using a thermal spraying machine. By setting the internal atmosphere in the connecting conduit to a negative pressure relative to the atmosphere near the intake end of the connecting conduit, the thermal spraying powder stored in the feeder is suctioned into the intake end of the connecting conduit. The thermal spraying powder suctioned into the intake end of the connecting conduit is carried to the discharge end of the connecting conduit, introduced inside a cylindrical air flow jetted from the nozzle provided in the thermal spraying machine or introduced into a combustion chamber provided in the thermal spraying machine or into the jet nozzle, softened or melted and jetted out.

### TECHNICAL FIELD

The present invention relates to a thermal spraying method and thermal spraying system for forming a thermal spray coating on a base material.

### BACKGROUND ART

A thermal spray coating is formed by heating a thermal spraying material and spraying the softened or melted thermal spraying material over a base material, and therefore the surface thereof is substantially not smooth but rough. For this reason, in applications requiring smoothness such as a paper manufacturing roll, etc., the surface of a thermal spray coating is polished to obtain desired surface roughness. However, the thermal spray coating generally has high hardness and polishing is often difficult. Especially in the case of a thermal spray coating obtained by thermal spraying cermet, it is necessary to apply polishing using diamond grain, which involves a considerable increase in cost. Therefore, there is a demand for means for obtaining a thermal spray coating with small surface roughness so as to omit or simplify polishing after thermal spraying.

Furthermore, a thermal spray coating has substantially a porous structure and may include through holes (holes which extend from the surface of the thermal spray coating to the base material). A thermal spray coating without any through holes is sometimes required depending on the application such as when thermal spraying is used as an alternative technology for plating. In such a case, through holes are conventionally prevented by providing a certain amount of thickness (several hundred μm) for the thermal spray coating. However, the cost basically increases as the thickness increases, and therefore the thermal spray coating is preferably as thin as possible. Thus, the thermal spray coating is required not to include air through holes however thin it may be.

As one of a means for responding to such a demand, a fine powder may be used as a thermal spraying material. If fine thermal spraying powder can be thermal sprayed, it is possible to obtain a thermal spray coating with small surface roughness. Furthermore, since the inner structure of the thermal spray coating becomes dense, even with a thin film, it is expected to obtain a thermal spray coating without containing any through holes. However, when fine powder is thermal sprayed, the following additional problems are produced. Thus, it is extremely difficult to obtain a dense thermal spray coating with small surface roughness.

First, a phenomenon called “spitting” may occur with a thermal spraying machine. Spitting refers to a phenomenon that a softened or melted thermal spraying material is adhered to or deposited on the inner wall of the jet nozzle of the thermal spraying machine and the depositions fall off and mix into the coating. Spitting may degenerate the quality of a thermal spray coating. Furthermore, the thermal spraying material deposited on the inner wall of the jet nozzle clogs the jet nozzle and prevents formation of the thermal spray coating itself. When the thermal spraying material is a fine powder, the powder is excessively melted and likely to stick to the inner wall of the jet nozzle and thereby produce spitting in particular.

Furthermore, the fluidity of thermal spraying powder decreases as the powder becomes finer, which causes problems like rippling and bridging in the feeder. When the supply of thermal spraying powder to the thermal spraying machine is not stable due to rippling, the quality of the thermal spray coating degenerates considerably. Furthermore, when thermal spraying powder forms a bridge, it is impossible to supply thermal spraying powder to the thermal spraying machine smoothly and the supply may be stopped in the worst case.

### DISCLOSURE OF THE INVENTION

It is an object of the present invention to provide a thermal spraying method and thermal spraying system capable of forming a dense thermal spray coating with small surface roughness.

In order to attain the above described object, the present invention provides a thermal spraying method for jetting thermal spraying powder supplied from a feeder through a connecting conduit by softening or melting the thermal spraying powder using a thermal spraying machine. The thermal spraying method includes the steps of suctioning thermal spraying powder stored in the feeder into the intake end of the connecting conduit by setting the internal atmosphere in the connecting conduit to a negative pressure relative to the atmosphere near the intake end of the connecting conduit, carrying the thermal spraying powder suctioned into the intake end of the connecting conduit to the discharge end of the connecting conduit, introducing the thermal spraying powder from the discharge end of the connecting conduit inside a cylindrical air flow jetted from a nozzle provided in the thermal spraying machine and jetting the thermal spraying powder by softening or melting the thermal spraying powder inside the air flow.

The present invention provides another thermal spraying method. The thermal spraying method includes the steps of suctioning thermal spraying powder stored in the feeder into the intake end of the connecting conduit by setting the internal atmosphere in the connecting conduit to a negative pressure relative to the atmosphere near the intake end of the connecting conduit, carrying the thermal spraying powder suctioned into the intake end of the connecting conduit to the discharge end of the connecting conduit and introducing the thermal spraying powder from the discharge end of the connecting conduit into a combustion chamber provided in a thermal spraying machine and jetting the thermal spraying powder directly from the combustion chamber to outside by softening or melting the thermal spraying powder using a combustion gas generated in the combustion chamber.

The present invention provides a further thermal spraying method. The thermal spraying method comprises the steps of suctioning the thermal spraying powder stored in the feeder into the intake end of the connecting conduit by setting the internal atmosphere in the connecting conduit to a negative pressure relative to the atmosphere near the intake end of the connecting conduit, carrying the thermal spraying powder suctioned into the intake end of the connecting conduit to the discharge end of the connecting conduit and introducing the thermal spraying powder from the discharge end of the connecting conduit into a place in a jet nozzle provided in the thermal spraying machine within 8 cm from the downstream end of the jet nozzle toward the upstream and jetting the thermal spraying powder by softening or melting the thermal spraying powder from the downstream end of the jet nozzle to the outside.

The present invention provides a still further thermal spraying method. The thermal spraying method comprises the steps of suctioning the thermal spraying powder stored in the feeder into the intake end of the connecting conduit by setting the internal atmosphere in the connecting conduit to a negative pressure relative to the atmosphere near the intake end of the connecting conduit, carrying the thermal spraying powder suctioned into the intake end of the connecting conduit to the discharge end of the connecting conduit and supplying a heat source discharged by the thermal spraying machine from the exhaust port to the outside, with the thermal spraying powder from the discharge end of the connecting conduit downstream from the exhaust port in a circulation direction of the heat source and jetting the thermal spraying powder by softening or melting the thermal spraying powder using the heat source.

The present invention also provides a thermal spraying system for jetting thermal spraying powder supplied from a feeder by softening or melting it in a thermal spraying machine. The thermal spraying system comprises a reservoir which stores the thermal spraying powder, a nozzle provided in a thermal spraying machine, the nozzle jetting a cylindrical air flow, a connecting conduit, the intake end of which is provided near the surface of the thermal spraying powder stored in the reservoir and the discharge end of which is provided inside the cylindrical air flow, the connecting conduit carrying thermal spraying powder from the intake end to the discharge end and introducing the thermal spraying powder from the discharge end to the inside of the cylindrical air flow, a mechanism which sets the internal atmosphere of the connecting conduit to a negative pressure relative to the atmosphere near the intake end of the connecting conduit to thereby suction the thermal spraying powder stored in the reservoir into the intake end of the connecting conduit and a mechanism which jets the thermal spraying powder discharged from the discharge end of the connecting conduit by softening or melting the thermal spraying powder inside the cylindrical air flow.

The present invention provides another thermal spraying system. The thermal spraying system comprises a reservoir which stores the thermal spraying powder, a combustion chamber provided in a thermal spraying machine, the combustion chamber generating a combustion gas, a connecting conduit, the intake end of which is provided near the surface of the thermal spraying powder stored in the reservoir and the discharge end of which is provided inside the combustion chamber, the connecting conduit carrying thermal spraying powder from the intake end to the discharge end and introducing the thermal spraying powder from the discharge end into the combustion chamber, a mechanism which sets the internal atmosphere of the connecting conduit to a negative pressure relative to the atmosphere near the intake end of the connecting conduit to thereby suction the thermal spraying powder stored in the reservoir into the intake end of the connecting conduit and a mechanism which jets the thermal spraying powder discharged from the discharge end of the connecting conduit directly from the combustion chamber to the outside by softening or melting the thermal spraying powder inside the combustion chamber.

The present invention provides a further thermal spraying system. The thermal spraying system comprises a reservoir which stores the thermal spraying powder, a jet nozzle provided in a thermal spraying machine, the jet nozzle jetting the softened or melted thermal spraying powder from the downstream end to the outside, a connecting conduit, the intake end of which is provided near the surface of the thermal spraying powder stored in the reservoir and the discharge end of which is provided inside the jet nozzle, the connecting conduit carrying thermal spraying powder from the intake end to the discharge end and introducing the thermal spraying powder from the discharge end to a place in the jet nozzle within 8 cm from the downstream end of the jet nozzle toward the upstream, a mechanism which sets the internal atmosphere of the connecting conduit to a negative pressure relative to the atmosphere near the intake end of the connecting conduit to thereby suction the thermal spraying powder stored in the reservoir into the intake end of the connecting conduit and a mechanism which jets the thermal spraying powder discharged from the discharge end of the connecting conduit from the downstream end of the jet nozzle to the outside by softening or melting the thermal spraying powder inside the jet nozzle.

The present invention provides a still further thermal spraying system. The thermal spraying system comprises a reservoir which stores the thermal spraying powder, an exhaust port provided in a thermal spraying machine, the exhaust port discharging a heat source to the outside, a connecting conduit, the intake end of which is provided near the surface of the thermal spraying powder stored in the reservoir and the discharge end of which is provided outside the exhaust port, the connecting conduit carrying thermal spraying powder from the intake end to the discharge end and supplying the thermal spraying powder from the discharge end to the heat source discharged from the exhaust port, a mechanism which sets the internal atmosphere of the connecting conduit to a negative pressure relative to the atmosphere near the intake end of the connecting conduit to thereby suction the thermal spraying powder stored in the reservoir into the intake end of the connecting conduit and a mechanism which jets the thermal spraying powder discharged from the discharge end of the connecting conduit by softening or melting the thermal spraying powder using the heat source discharged from the exhaust port.

### BRIEF DESCRIPTION OF THE DRAWINGS

FIG. 1(a) is a cross-sectional side view showing a thermal spraying machine according to a first embodiment of the present invention;

FIG. 1(b) is a front view of the thermal spraying machine in FIG. 1(a);

FIG. 1(c) is a rear view of the thermal spraying machine in FIG. 1(a);

FIG. 2 is a schematic view showing a feeder according to the first embodiment of the present invention;

FIG. 3 is a schematic view showing a thermal spraying machine according to a second embodiment of the present invention;

FIG. 4 is a schematic view showing a thermal spraying machine according to a third embodiment of the present invention; and

FIG. 5 is a cross-sectional side view showing a thermal spraying machine according to a fourth embodiment of the present invention.

### BEST MODE FOR CARRYING OUT THE INVENTION

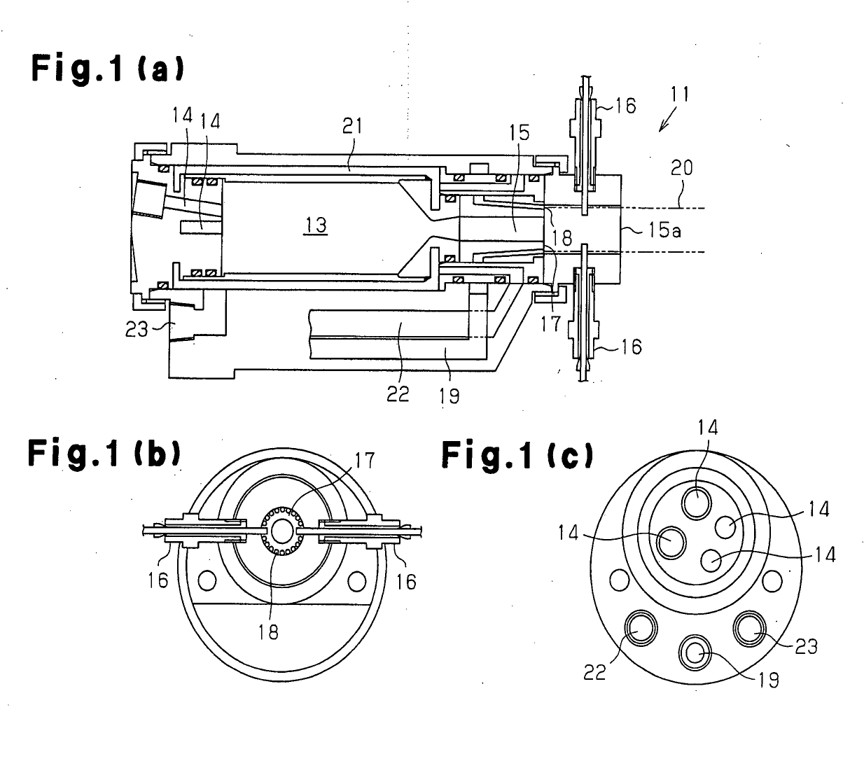

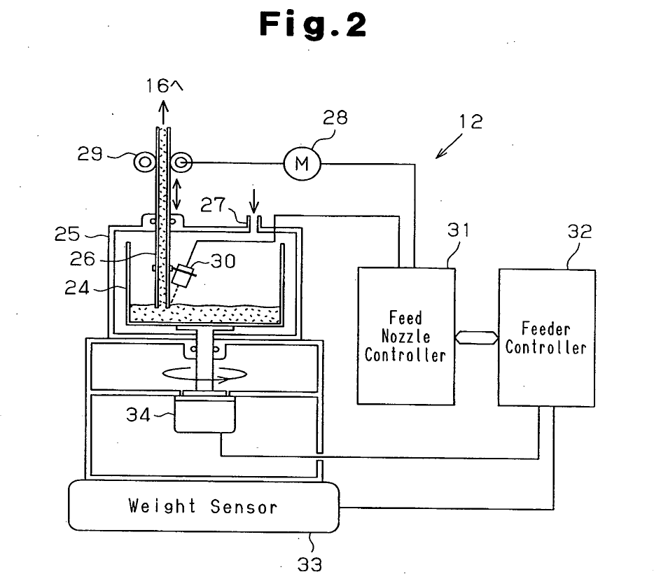

A first embodiment of the present invention will be explained with reference to FIGS. 1(a) to 2.

A thermal spraying system according to this embodiment is provided with a high-speed flame spraying machine 11 (hereinafter also referred to as “thermal spraying gun 11”) as a thermal spraying machine show in FIGS. 1(a) to 1(c) and a feeder 12 shown in FIG. 2.

First, the thermal spraying gun 11 will be explained with reference to FIGS. 1(a) to 1(c). The thermal spraying gun 11 jets thermal spraying powder as a thermal spraying material by softening or melting it using a combustion gas of fuel and oxygen. The thermal spraying gun 11 is provided with a combustion chamber 13 where combustion of fuel and oxygen takes place. The combustion chamber 13 is open to the outside at the rear end (left side in FIG. 1(a)) of the thermal spraying gun 11 through a first hole 14. The first hole 14 serves as a channel to introduce fuel and oxygen into the combustion chamber 13. The combustion chamber 13 is also open to the outside at an exhaust port 15a at the front end (right side in FIG. 1(a)) of the thermal spraying gun 11 through a second hole 15. The second hole 15 serves as a channel to discharge a combustion gas produced by combustion of fuel and oxygen in the combustion chamber 13 from the exhaust port 15a to the outside.

A forward-facing (facing downstream in the circulation direction of the combustion gas in the second hole 15) stepped surface 17 is formed at some midpoint in the second hole 15. On the stepped surface 17, a nozzle 18 is formed, which jets a cylindrical air flow 20 toward the downstream direction in the circulation direction of the combustion gas. The compressed gas making up the cylindrical air flow 20 is supplied from a supply source of a compressed gas (not shown) to the thermal spraying gun 11, passed through an introduction path 19 and is jetted from the nozzle 18. The nozzle 18 is made up of a plurality of circular holes and these circular holes are arranged in a ring shape on the stepped surface 17 (see FIG. 1(b)). The combustion gas circulating through the second hole 15 toward the exhaust port 15a passes inside the cylindrical air flow 20 jetted from the nozzle 18.

A carrier tube 16 which extends from the feeder 12 (see FIG. 2) is connected at some midpoint in the second hole which is a position downstream from the nozzle 18 in the circulation direction of the combustion gas. The thermal spraying powder carried from the feeder 12 to the thermal spraying gun 11 through the carrier tube 16 is supplied to the combustion gas circulating inside the cylindrical air flow 20 toward the exhaust port 15a and softened or melted by the combustion gas inside the cylindrical air flow 20 and jetted out.

A channel 21 for a coolant to cool the combustion chamber 13 is formed outside the combustion chamber 13. The coolant is introduced from a supply source (not shown) of the coolant through an introduction path 22 to the channel 21 and exhausted through an exhaust path 23.

Then, the feeder 12 will be explained with reference to FIG. 2. The feeder 12 supplies thermal spraying powder to the thermal spraying gun 11. The feeder 12 is provided with a reservoir 24 which stores the thermal spraying powder. The reservoir 24 is housed in a sealed container 25. The reservoir 24 is provided with a feed nozzle 26. The bottom end (upstream end) of the feed nozzle 26 is placed near the surface of the thermal spraying powder stored in the reservoir 24 and the top end (downstream end) of the feed nozzle 26 is connected to the carrier tube 16 (see FIG. 1(a)) and led out of the sealed container 25. The state in which the bottom end of the feed nozzle 26 is placed “near the surface of the thermal spraying powder stored in the reservoir 24” means not only a state in which there is a small gap between the bottom end of the feed nozzle 26 and the surface of the thermal spraying powder but also a state in which the bottom end of the feed nozzle 26 contacts the surface of the thermal spraying powder and a state in which the bottom end of the feed nozzle 26 is slightly buried in the thermal spraying powder.

An inlet 27 is formed in the sealed container 25 to introduce a carrier gas (e.g., nitrogen gas) into the sealed container 25. When the carrier gas is fed into the sealed container 25 from the inlet 27, the atmosphere in the feed nozzle 26 becomes a negative pressure relative to the atmosphere near the bottom end of the feed nozzle 26, and the thermal spraying powder is suctioned together with the carrier gas into the feed nozzle 26. The thermal spraying powder suctioned into the feed nozzle 26 is passed through the carrier tube 16 together with the carrier gas and carried to the thermal spraying gun 11.

The feed nozzle 26 is moved up and down by a stepping motor 28 through a gear mechanism 29. The driving of the stepping motor 28 is controlled by a feed nozzle controller 31 based on the surface position of the thermal spraying powder in the reservoir 24 detected by a laser sensor 30. The feed nozzle controller 31 is under feedback control of a feeder controller 32 based on information on the supply speed of the thermal spraying powder detected by a weight sensor 33. The surface of the thermal spraying powder in the reservoir 24 is smoothed by a smoother (not shown) by a motor 34 driving the rotation of the reservoir 24.

It is an essential condition for the thermal spraying powder used in the thermal spraying system of this embodiment to have D₉₀% of no more than 20 μm. D₉₀% is the diameter of grains making up powder when a value obtained by adding up the volume of the grains in ascending order of grain diameter is equal to 90% of the sum of the volume of all the grains. When D₉₀% exceeds 20 μm, it is not possible to obtain a dense thermal spray coating with small surface roughness. The value of D₉₀% of the thermal spraying powder is measured using a laser diffraction type particle size analyzer (e.g., “LA-300” manufactured by HORIBA, Ltd.).

This embodiment has the following advantages.

The thermal spraying powder is softened or melted inside the cylindrical air flow 20 jetted from the nozzle 18, passed inside the cylindrical air flow 20, and jetted out. This makes it possible to suppress the adhesion and deposition of the softened or melted thermal spraying powder on the inner wall of the second hole 15 and suppress the generation of spitting.

The feeder 12 sets the atmosphere in the feed nozzle 26 to a negative pressure relative to the atmosphere near the bottom end of the feed nozzle 26 and thereby suctions the thermal spraying powder together with the carrier gas into the feed nozzle 26. For this reason, intake of the thermal spraying powder into the feed nozzle 26 is not dependent on the fluidity of the thermal spraying powder. Therefore, even if the thermal spraying powder is fine grains, it is possible to prevent the thermal spraying powder from forming a bridge or prevent the supply of thermal spraying powder from rippling.

The thermal spraying system of this embodiment suppresses spitting at the thermal spraying gun 11 and bridging and rippling at the feeder 12. Thus, it is possible to supply and thermal-spray fine thermal spraying powder stably and form a dense thermal spray coating with small surface roughness.

The high-speed flame spraying method accelerates thermal spraying powder much more than other thermal spraying methods and causes thermal spraying powder to collide with the base material strongly. For this reason, it is possible to form a dense thermal spray coating with small surface roughness more reliably.

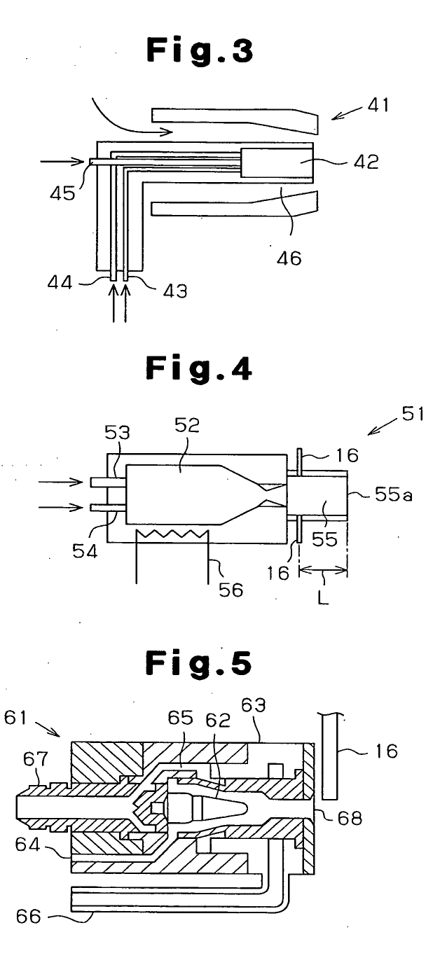

Hereinafter, a second embodiment of the present invention will be explained with reference to FIG. 3.

As the thermal spraying machine, the thermal spraying system according to this embodiment uses a high-speed flame spraying machine 41 (hereinafter also referred to as “thermal spraying gun 41”) shown in FIG. 3 instead of the thermal spraying gun 11 according to the first embodiment. Thus, a feeder 12 and thermal spraying powder used are the same as those in the first embodiment, and therefore explanations thereof will be omitted.

The thermal spraying gun 41 jets thermal spraying powder by softening or melting it using a combustion gas of fuel and oxygen. The thermal spraying gun 41 is provided with a combustion chamber 42 where combustion of fuel and oxygen takes place. The combustion chamber 42 is directly open to the outside at the front end (right side in FIG. 3) of the thermal spraying gun 41. The combustion chamber 42 is also open to the outside at the rear end (bottom left in FIG. 3) of the thermal spraying gun 41 through the first holes 43 and 44. The first holes 43 and 44 serve as channels for introducing fuel and oxygen into the combustion chamber 42. The combustion chamber 42 is also open to the outside at the rear end (left side in FIG. 3) of the thermal spraying gun 41 through a second hole 45. The second hole 45 is connected to a carrier tube 16 (not shown in FIG. 3) which extends from a feeder 12 (see FIG. 2). Thermal spraying powder carried from the feeder 12 through the carrier tube 16 into the thermal spraying gun 41 is passed through the second hole 45 and supplied to the combustion chamber 42 and softened or melted by a combustion gas in the combustion chamber 42 and directly jetted out from the combustion chamber 42 to the outside.

A channel 46 for a coolant (air) to cool the combustion chamber 42 is formed outside the combustion chamber 42. The coolant is introduced from a supply source (not shown) of the coolant into the channel 46.

In this embodiment, the thermal spraying powder is softened or melted by the combustion gas in the combustion chamber 42 and directly jetted out from the combustion chamber 42 to the outside. This prevents the softened or melted thermal spraying powder from adhering and depositing onto the inner wall of the jet nozzle and prevents spitting from occurring.

The flying speed of the thermal spraying powder jetted out from the thermal spraying gun 41 is slower than the flying speed of the thermal spraying powder jetted out from a conventional high-speed flame spraying machine provided with a jet nozzle. For this reason, a thermal spray coating obtained is likely to contain many pores. However, the thermal spraying powder used in this embodiment is fine grains having a D₉₀% of no more than 20 μm, and therefore it is easily softened or melted. Therefore, even if the flying speed of the thermal spraying powder is slow, it is possible to obtain a dense thermal spray coating. Furthermore, the thermal spraying gun 41 generally uses propylene as a fuel, and therefore the temperature of the combustion gas is high and it is thereby possible to soften or melt thermal spraying powder more reliably than a conventional high-speed flame spraying machine.

Hereafter, a third embodiment of the present invention will be explained with reference to FIG. 4.

As the thermal spraying machine, the thermal spraying system according to this embodiment uses a high-speed flame spraying machine 51 (hereinafter also referred to as “thermal spraying gun 51”) shown in FIG. 4 instead of the thermal spraying gun 11 according to the first embodiment. Thus, a feeder 12 and thermal spraying powder used are the same as those in the first embodiment, and therefore explanations thereof will be omitted.

The thermal spraying gun 51 jets thermal spraying powder by softening or melting it using a combustion gas of fuel and oxygen. The thermal spraying gun 51 is provided with a combustion chamber 52 where combustion of fuel and oxygen takes place. The combustion chamber 52 is open to the outside at the rear end (left side in FIG. 4) of the thermal spraying gun 51 through first holes 53 and 54. The first holes 53 and 54 serve as channels for introducing fuel and oxygen into the combustion chamber 52. The combustion chamber 52 is also open to the outside at an exhaust port 55a at the front end (right side in FIG. 4) of the thermal spraying gun 51 through a second hole 55 (jet nozzle). The second hole 55 serves as a channel to discharge combustion gas produced when combustion of fuel and oxygen takes place in the combustion chamber 52 from the exhaust port 55a to the outside. The second hole 55 is connected to a carrier tube 16 which extends from the feeder 12 (see FIG. 2). Thermal spraying powder carried from the feeder 12 through the carrier tube 16 into the thermal spraying gun 51 is supplied to the combustion gas circulating through the second hole 55 toward the exhaust port 55a, softened or melted by the combustion gas in the second hole 55 and jetted out.

The length L from the downstream end of the carrier tube 16, that is, the supply port of the thermal spraying powder, to the exhaust port 55a is no more than 8 cm, or preferably no more than 6.5 cm. By setting this length L to 8 cm or less, it is possible to prevent spitting from occurring and setting it to 6.5 cm or less further increases the effect.

A channel 56 for a coolant (water) to cool the combustion chamber 52 is formed outside the combustion chamber 52. The coolant is introduced from a supply source (not shown) of the coolant into the channel 56.

Compared to a conventional high-speed flame spraying machine, the length L from the supply port of the thermal spraying powder to the exhaust port 55a of the thermal spraying gun 51 is short. Thus, the flying speed of the thermal spraying powder jetted out from the thermal spraying gun 51 is slower than the flying speed of the thermal spraying powder jetted out from a conventional high-speed flame spraying machine. For this reason, a thermal spray coating obtained is likely to contain many pores. However, the thermal spraying material used in this embodiment is fine grains having a D_{90%} of no more than 20 μm, and therefore it is easily softened or melted. Therefore, even if the flying speed of the thermal spraying powder is slow, it is possible to obtain a dense thermal spray coating. Furthermore, by narrowing the inner diameter of the second hole 55, which is the channel for the combustion gas, it is possible to increase the flying speed of thermal spraying powder of the thermal spraying gun 51.

Hereafter, a fourth embodiment of the present invention will be explained with reference to FIG. 5.

As the thermal spraying machine, the thermal spraying system according to this embodiment uses a plasma thermal spraying machine 61 (hereinafter also referred to as “thermal spraying gun 61”) shown in FIG. 5 instead of the thermal spraying gun 11 according to the first embodiment. Thus, a feeder 12 and thermal spraying powder used are the same as those in the first embodiment, and therefore explanations thereof will be omitted.

The thermal spraying gun 61 discharges thermal spraying powder by softening or melting it using a plasma jet. The thermal spraying gun 61 is provided with a cathode 62 and an anode 63. A plasma jet is formed through ignition of arc discharge between the two electrodes 62 and 63. The thermal spraying gun 61 is provided with an introduction path 64 for a plasma working gas (argon, helium, etc.). The plasma working gas is supplied to close to the electrodes 62 and 63 through the introduction path 64 from a supply source (not shown). A channel 65 for a coolant (water) to cool the electrodes 62 and 63 is formed around the electrodes 62 and 63. The coolant is introduced from a supply source (not shown) into the channel 65 through an introduction path 66 and exhausted through an exhaust path 67.

An exhaust port 68 for discharging a plasma jet is formed at the front end (right side in FIG. 5) of the thermal spraying gun 61. In front of the exhaust port 68, the downstream end of a carrier tube 16 which extends from the feeder 12 (see FIG. 2) is provided. The thermal spraying powder carried from the feeder 12 through the carrier tube 16 to the thermal spraying gun .61 is supplied to the plasma jet discharged from the exhaust port 68 is softened or melted by the plasma jet outside the thermal spraying gun 61 and jetted out.

The thermal spraying gun 61 does not soften or melt thermal spraying powder inside the thermal spraying machine as in the case of a conventional thermal spraying machine but softens or melts thermal spraying powder outside the thermal spraying gun 61. This eliminates the possibility that spitting may occur.

The above described embodiments may also be modified as follows.

The first to third embodiments use the high-speed flame spraying machine 11 as the thermal spraying machine, but the present invention may also be implemented using other gas-based thermal spraying machines. Furthermore, the present invention may also be implemented using an electric thermal spraying machine such as a plasma thermal spraying machine.

The fourth embodiment uses the plasma thermal spraying machine 61 as the thermal spraying machine, but the present invention may also be implemented using a gas-based thermal spraying machine such as a high-speed flame spraying machine.

The first embodiment uses circular holes for the nozzle 18, but it may also be arc-shaped long holes.

The first embodiment forms the nozzle 18 in a ring shape, but the nozzle 18 may also be formed in a polygonal ring shape.

The first embodiment uses two carrier tubes 16 connected to the thermal spraying gun 11, but the number of the carrier tubes 16 may also be one or three or more. The fourth embodiment uses one carrier tube 16 connected to the thermal spraying gun 61, but the number of the carrier tubes 16 may also be two or more.

### EXAMPLE

The present invention will be explained more specifically using Examples and Comparative Examples as follows.

Using a thermal spraying system combining a thermal spraying machine and a feeder as shown in Table 1, thermal spraying powder having a composition and particle size distribution as shown in Table 1 was thermal-sprayed onto a base material (SS400 steel sheet). For the thermal spraying powder whose thermal spray coating was successfully formed on the base material, the surface roughness and denseness of the thermal spray coating were evaluated as shown below and the results are shown in Table 1.

Evaluations in the column of the coating formation in Table 1 were made in which cases of successful formation of a thermal spray coating were marked with ∘, cases of a failure to form a thermal spray coating due to spitting in the thermal spraying machine were marked with x, and cases of a failure to supply thermal spraying powder from the feeder to the thermal spraying machine resulting in a failure to form a thermal spray coating were marked with XX. “AM-30” and “PL-25” in the field of the feeder in Table 1 denote trade names of the feeders manufactured by Technoserve Co., Ltd., and “1264” is a trade name of the feeder manufactured by PRAXAIR, Inc.

The thermal spraying conditions in the respective Examples and Comparative Examples are as follows:

### Examples 1 to 4

### Comparative Examples 1, 6 to 9.

Thermal spraying machine: high-speed flame spraying machine “θ-Gun” (corresponds to the thermal spraying machine 11 according to the first embodiment) manufactured by Whitco Japan, oxygen flow rate: 1900 scfh (893 ml/min), kerosene flow rate: 5.1 gph (0.32 1/min), thermal spraying distance: 250 mm Example 5

### Comparative Examples 10 and 11

Thermal spraying machine: plasma thermal spraying machine “SG-100” (corresponds to the thermal spraying machine 61 according to the fourth embodiment) manufactured by PRAXAIR, Inc., current: 700 A, Ar: 50 psi (345 kPa), He: 90 psi (620 kpa), thermal spraying powder supply unit: external supply type

### Example 6

Thermal spraying machine: high-speed flame spraying machine “Diamond jet standard type (DJ-STD)” (corresponds to the thermal spraying machine 41 according to the second embodiment) manufactured by SULZER METCO, oxygen flow rate: 40 scales, propylene flow rate: 38 scales, airflow rate: 47 scales, thermal spraying distance: 200 mm

### Comparative Examples 2 to 4, 12 to 15

Thermal spraying machine: high-speed flame spraying machine “JP-5000” manufactured by PRAXAIR/TAFA, length of barrel (jet nozzle): 10.16 cm (=4 inches), oxygen flow rate: 1900 scfh (893 ml/min), kerosene flow rate: 5.1 gph (0.32 1/min), thermal spraying distance: 380 mm

### Comparative Example 5

Thermal spraying machine: high-speed flame spraying machine “JET-KOTE” manufactured by DELORO STEELITE COATING, oxygen flow rate: 1000 scales, propylene flow rate: 63 scales, pilot gas (H₂) flow rate: 10 scales, pilot gas (O₂) flow rate: 10 scales, thermal spraying distance: 200 mm

Evaluation of surface roughness of thermal spray coating

The surface roughness Ra of a thermal spray coating having a thickness of 200 μm formed on a base material was measured. Evaluations were made with cases having a surface roughness Ra of less than 1.0 μm measured under the following conditions marked with ⊚, 1.0 μm or more and less than 2.0 μm marked with ∘, 2.0 μm or more and less than 3.0 μm marked with Δand 3.0 μm or more marked with X.

Measuring conditions for surface roughness Ra

Measuring machine: surface roughness measuring machine “Surfcom 1400D-12” manufactured by Tokyo Seimitsu Co., Ltd., measuring length: 10.0 mm, cutoff wavelength: 0.8 mm, measuring speed: 0.30 mm/sec, edge: r=5 μm

Evaluation of denseness of thermal spray coating

A thermal spray coating having a thickness of 30 μm formed on a base material was subjected to a salt-spray test compliant with JIS Z 2371. That is, salt water was sprayed over the surface of a base material covered with a thermal spray coating. 24 hours after salt water was sprayed, the appearance was visually checked and evaluations were made in which cases with rust were marked with x and cases with no rust marked were with ∘.

TABLE 1

| | | | Thermal spraying | | | | | | |
|---|---|---|---|---|---|---|---|---|---|
| | | | powder | | | | | | |
| | | | | Particle | | | | | |
| | | | | size | | | Evaluation | | |
| | Thermal | | | distribution | | | | Surface | |
| | spraying | | Compo- | (μm) | | | Coating | roughness | |
| | machine | Feeder | sition | D_{10%} | D_{50%} | D_{90%} | formation | Ra (μm) | Denseness |
| Ex. 1 | θ-gun | AM-30 | WC/12Co | 0.6 | 1.8 | 5.2 | ◯ | ⊚ (0.73) | ◯ |
| Ex. 2 | θ-gun | AM-30 | WC/12Co | 0.9 | 3.3 | 6.3 | ◯ | ⊚ (0.99) | ◯ |
| Ex. 3 | θ-gun | AM-30 | WC/12Co | 2.1 | 6.4 | 11.7 | ◯ | ◯ (1.52) | ◯ |
| Ex. 4 | θ-gun | AM-30 | Ni—20Cr | 2.7 | 6.0 | 10.1 | ◯ | ◯ (1.48) | ◯ |
| Ex. 5 | SG-100 | AM-30 | WC/12Co | 0.6 | 1.8 | 5.2 | ◯ | ⊚ (0.83) | ◯ |
| Ex. 6 | DJ-STD | AM-30 | WC/12Co | 0.6 | 1.8 | 5.2 | ◯ | ⊚ (0.82) | ◯ |
| C. Ex. 1 | θ-gun | AM-30 | WC/12Co | 9.7 | 23.5 | 37.1 | ◯ | Δ (2.78) | ◯ |
| C. Ex. 2 | JP-5000 | AM-30 | WC/12Co | 0.6 | 1.8 | 5.2 | X | — | — |
| C. Ex. 3 | JP-5000 | AM-30 | WC/12Co | 0.9 | 3.3 | 6.3 | X | — | — |
| C. Ex. 4 | JP-5000 | AM-30 | WC/12Co | 2.1 | 6.4 | 11.7 | X | — | — |
| C. Ex. 5 | Jet-Kote | AM-30 | WC/12Co | 0.6 | 1.8 | 5.2 | X | — | — |
| C. Ex. 6 | θ-gun | PL-25 | WC/12Co | 0.6 | 1.8 | 5.2 | XX | — | — |
| C. Ex. 7 | θ-gun | PL-25 | WC/12Co | 0.9 | 3.3 | 6.3 | XX | — | — |
| C. Ex. 8 | θ-gun | PL-25 | WC/12Co | 2.1 | 6.4 | 11.7 | XX | — | — |
| C. Ex. 9 | θ-gun | 1264 | WC/12Co | 0.6 | 1.8 | 5.2 | XX | — | — |
| C. Ex. 10 | SG-100 | PL-25 | WC/12Co | 0.6 | 1.8 | 5.2 | XX | — | — |
| C. Ex. 11 | SG-100 | 1264 | WC/12Co | 0.6 | 1.8 | 5.2 | XX | — | — |
| C. Ex. 12 | JP-5000 | PL-25 | WC/12Co | 9.7 | 23.5 | 37.1 | X | — | — |
| C. Ex. 13 | JP-5000 | PL-25 | WC/12Co | 18.6 | 27.7 | 42.8 | ◯ | X (3.85) | X |
| C. Ex. 14 | JP-5000 | PL-25 | Ni—20Cr | 8.6 | 22.9 | 35.2 | X | — | — |
| C. Ex. 15 | JP-5000 | PL-25 | Ni—20Cr | 20.1 | 30.2 | 45.6 | ◯ | X (3.92) | X |

As shown in Table 1, all the thermal spray coatings obtained in Examples 1 to 6 were evaluated with regard to surface roughness as excellent or good (⊚ or ∘) and evaluated with regard to denseness as good (∘). On the contrary, the cases of Comparative Examples 1 to 15 could not even form a thermal spray coating except for Comparative Example 1, Comparative Example 13 and Comparative Example 15, or although they could form some thermal spray coating, their surface roughness and denseness were evaluated as unacceptable (X).

1. A thermal spraying method for jetting thermal spraying powder supplied from a feeder through a connecting conduit having intake and discharge ends by softening or melting the thermal spraying powder using a thermal spraying machine, the method comprising:
suctioning thermal spraying powder stored in said feeder into the intake end of said connecting conduit by setting the internal atmosphere in said connecting conduit to a negative pressure relative to the atmosphere near the intake end of said connecting conduit;
carrying the thermal spraying powder suctioned into the intake end of said connecting conduit to the discharge end of said connecting conduit; and
introducing the thermal spraying powder from the discharge end of said connecting conduit into a cylindrical air flow jetted from a nozzle provided in said thermal spraying machine and jetting said thermal spraying powder by softening or melting said thermal spraying powder inside the air flow.

2. A thermal spraying method for jetting thermal spraying powder supplied from a feeder through a connecting conduit having intake and discharge ends by softening or melting the thermal spraying powder using a thermal spraying machine, the method comprising:
suctioning thermal spraying powder stored in said feeder into the intake end of said connecting conduit by setting the internal atmosphere in said connecting conduit to a negative pressure relative to the atmosphere near the intake end of said connecting conduit;
carrying the thermal spraying powder suctioned into the intake end of said connecting conduit to the discharge end of said connecting conduit; and
introducing the thermal spraying powder from the discharge end of said connecting conduit into a combustion chamber provided in said thermal spraying machine and jetting said thermal spraying powder directly from said combustion chamber to the outside by softening or melting said thermal spraying powder using a combustion gas generated in said combustion chamber.

3. A thermal spraying method for jetting thermal spraying powder supplied from a feeder through a connecting conduit having intake and discharge ends by softening or melting the thermal spraying powder using a thermal spraying machine, the method comprising:
suctioning thermal spraying powder stored in said feeder into the intake end of said connecting conduit by setting the internal atmosphere in said connecting conduit to a negative pressure relative to the atmosphere near the intake end of said connecting conduit;
carrying the thermal spraying powder suctioned into the intake end of said connecting conduit to the discharge end of said connecting conduit; and
introducing the thermal spraying powder from the discharge end of said connecting conduit into a place in a jet nozzle provided in said thermal spraying machine, the jet nozzle including a downstream end, with said place being within 8 cm from the downstream end of said jet nozzle toward the upstream and jetting said thermal spraying powder by softening or melting said thermal spraying powder from the downstream end of said jet nozzle to the outside

4. A thermal spraying method for jetting thermal spraying powder supplied from a feeder through a connecting conduit having intake and discharge ends by softening or melting the thermal spraying powder using a thermal spraying machine having an exhaust port, the method comprising:
suctioning thermal spraying powder stored in said feeder into the intake end of said connecting conduit by setting the internal atmosphere in said connecting conduit to a negative pressure relative to the atmosphere near the intake end of said connecting conduit;
carrying the thermal spraying powder suctioned into the intake end of said connecting conduit to the discharge end of said connecting conduit; and
supplying a heat source discharged by said thermal spraying machine from the exhaust port to the outside, with the thermal spraying powder from the discharge end of said connecting conduit downstream from said exhaust port in a circulation direction of said heat source and jetting said thermal spraying powder by softening or melting said thermal spraying powder using said heat source.

5. The method according to claim 1 90% of the sum of the volume of all the grains, in the thermal spraying powder is constituted by the added-up volume of grains the diameters of which are no more than 20 μm.

6. A thermal spraying system for jetting thermal spraying powder supplied from a feeder by softening or melting the thermal spraying powder using a thermal spraying machine, the system comprising:
a reservoir which stores the thermal spraying powder;
a nozzle provided in said thermal spraying machine, said nozzle jetting a cylindrical air flow;
a connecting conduit having intake and discharge ends, the intake end of which is provided near the surface of the thermal spraying powder stored in said reservoir and the discharge end of which is provided inside said cylindrical air flow, said connecting conduit carrying thermal spraying powder from the intake end to the discharge end and introducing the thermal spraying powder from the discharge end to the inside of said cylindrical air flow;
a mechanism which sets the internal atmosphere of said connecting conduit to a negative pressure relative to the atmosphere near the intake end of said connecting conduit to thereby suction the thermal spraying powder stored in said reservoir into the intake end of said connecting conduit; and
a mechanism which jets the thermal spraying powder discharged from the discharge end of said connecting conduit by softening or melting said thermal spraying powder inside said cylindrical air flow.

7. A thermal spraying system for jetting thermal spraying powder supplied from a feeder by softening or melting the thermal spraying powder using a thermal spraying machine, the system comprising:
a reservoir which stores the thermal spraying powder;
a combustion chamber provided in said thermal spraying machine, said combustion chamber generating a combustion gas;
a connecting conduit having intake and discharge ends, the intake end of which is provided near the surface of the thermal spraying powder stored in said reservoir and the discharge end of which is provided inside said combustion chamber, said connecting conduit carrying thermal spraying powder from the intake end to the discharge end and introducing the thermal spraying powder from the discharge end into said combustion chamber;
a mechanism which sets the internal atmosphere of said connecting conduit to a negative pressure relative to the atmosphere near the intake end of said connecting conduit to thereby suction the thermal spraying powder stored in said reservoir into the intake end of said connecting conduit; and
a mechanism which jets the thermal spraying powder discharged from the discharge end of said connecting conduit directly from said combustion chamber to the outside by softening or melting said thermal spraying powder inside said combustion chamber.

8. A thermal spraying system for jetting thermal spraying powder supplied from a feeder by softening or melting the thermal spraying powder using a thermal spraying machine, the system comprising:
a reservoir which stores the thermal spraying powder;
a jet nozzle provided in said thermal spraying machine, the jet nozzle including a downstream end, said jet nozzle jetting the softened or melted thermal spraying powder from the downstream end to the outside;
a connecting conduit having intake and discharge ends, the intake end of which is provided near the surface of the thermal spraying powder stored in said reservoir and the discharge end of which is provided inside said jet nozzle, said connecting conduit carrying thermal spraying powder from the intake end to the discharge end and introducing the thermal spraying powder from the discharge end to a place in said jet nozzle, with said place being within 8 cm from the downstream end of said jet nozzle toward the upstream;
a mechanism which sets the internal atmosphere of said connecting conduit to a negative pressure relative to the atmosphere near the intake end of said connecting conduit to thereby suction the thermal spraying powder stored in said reservoir into the intake end of said connecting conduit; and
a mechanism which jets the thermal spraying powder discharged from the discharge end of said connecting conduit from the downstream end of said jet nozzle to the outside by softening or melting said thermal spraying powder inside said jet nozzle.

9. A thermal spraying system for jetting thermal spraying powder supplied from a feeder by softening or melting the thermal spraying powder using a thermal spraying machine, the system comprising:
a reservoir which stores the thermal spraying powder;
an exhaust port provided in said thermal spraying machine, said exhaust port discharging a heat source to the outside;
a connecting conduit having intake and discharge ends, the intake end of which is provided near the surface of the thermal spraying powder stored in said reservoir and the discharge end of which is provided outside said exhaust port, said connecting conduit carrying thermal spraying powder from the intake end to the discharge end and supplying the thermal spraying powder from the discharge end to the heat source discharged from said exhaust port;
a mechanism which sets the internal atmosphere of said connecting conduit to a negative pressure relative to the atmosphere near the intake end of said connecting conduit to thereby suction the thermal spraying powder stored in said reservoir into the intake end of said connecting conduit; and
a mechanism which jets the thermal spraying powder discharged from the discharge end of said connecting conduit by softening or melting said thermal spraying powder using the heat source discharged from said exhaust port.

10. The system according to claim 6, 90% of the sum of the volume of all the grains, in the thermal spraying powder is constituted by the added-up volume of grains the diameters of which are no more than 20 pm.

11. The system according to claim 7, wherein 90% of the sum of the volume of all the grains in the thermal spraying powder is constituted by the added-up volume of grains the diameters of which are no more than 20 μm.

12. The system according to claim 8, wherein 90% of the sum of the volume of all the grains in the thermal spraying powder is constituted by the added-up volume of grains the diameters of which are no more than 20 μm.

13. The system according to claim 9, wherein 90% of the sum of the volume of all the grains in the thermal spraying powder is constituted by the added-up volume of grains the diameters of which are no more than 20 μm.

14. The method according to claim 2, wherein 90% of the sum of the volume of all the grains in the thermal spraying powder is constituted by the added-up volume of grains the diameters of which are no more than 20 μm.

15. The method according to claim 3, wherein 90% of the sum of the volume of all the grains in the thermal spraying powder is constituted by the added-up volume of grains the diameters of which are no more than 20 μm.

16. The method according to claim 4, wherein 90% of the sum of the volume of all the grains in the thermal spraying powder is constituted by the added-up volume of grains the diameters of which are no more than 20 μm.
